(19) United States
(12) Patent Application Publication
(10) Pub. No.: US 2009/0224610 A1
(43) Pub. Date: Sep. 10, 2009

(54) SYSTEMS AND METHODS FOR GENERATING HIGH POWER, WIDEBAND MICROWAVE RADIATION USING VARIABLE CAPACITANCE VOLTAGE MULTIPLICATION

(75) Inventors: Mikhail Fuks, Albuquerque, NM (US); Edl Schamiloglu, Albuquerque, NM (US); James Benford, Lafayette, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: General Dynamics Ordnance and Tactical Systems- Canada Inc., Le Gardeur (CA)

(21) Appl. No.: 11/924,978

(22) Filed: Oct. 26, 2007

Related U.S. Application Data
(60) Provisional application No. 60/869,533, filed on Dec. 11, 2006.

(51) Int. Cl. H03K 3/00; H01G 5/00

(52) U.S. Cl. 307/108; 361/277

(57) ABSTRACT

Systems and methods for generating high power, wideband microwave radiation pulses. A pulse generating device includes a capacitor as a primary electric energy store, a source of mechanical or chemical energy for modifying the capacitance of the capacitor, which then connects to a transmission line or pulse forming line (PFL) with many times increased electromagnetic energy, a switch and a broadband radiating element such as an antenna. A high voltage pulse and accordingly a high amount of electromagnetic energy is formed owing to decreasing the capacitance of an initially charged capacitor by dynamically changing a configuration of capacitor electrodes using mechanical work. The final configuration forms a transmission line, with the voltage and electric energy increased by the ratio of initial capacitance to final capacitance when the charge on the modifying capacitor is conserved. A switch connects opposite charged parts of the transmission line, and the resulting high voltage in the form of a pulse or multiple pulses propagates along the transmission line to a load (antenna) to generate one or more electromagnetic pulses.

### CROSS-REFERENCES TO RELATED APPLICATIONS

This application claims the benefit of U.S. Provisional Application Ser. No. 60/869,533, filed Dec. 11, 2006, the entire disclosure of which is incorporated by reference for all purposes.

### BACKGROUND

The present invention relates generally to electromagnetic munitions, and more particularly to systems and methods for generating electromagnetic pulses based on variable capacitance voltage multiplication.

Electromagnetic munitions are typically designed to produce electromagnetic pulses capable of interacting with and disrupting or destroying electronic systems. A generated electromagnetic pulse typically couples through cables, ventilation grills, or gaps in target systems, producing overheating and burnout, punch-through or avalanche breakdown effects in semiconductors and electronics. Use of electromagnetic munitions in combat in respectable numbers would represent an important milestone in shifting warfare away from physically lethal to electronically lethal attacks on electronic targets. Typical uses in war scenarios would be disruption of integrated air defense and command control and communications systems. Use of such electromagnetic munitions thus provides the user with a military advantage.

Whatever the mode of attack, microwave energy can propagate to the target system internal electronics through two generic types of coupling paths: front-door coupling and back-door coupling. “Front-door” denotes coupling through intentional receptors for electromagnetic energy such as antennas and sensors, with power flowing through the transmission lines designed for that purpose and terminating in a detector or receiver. “Back-door” coupling denotes coupling through apertures intended for other purposes or incidental to the construction of the target system. Back-door coupling paths include seams, cracks, hatches, access panels, windows, doors, and unshielded or improperly shielded wires.

In general, the power coupled to internal circuitry, P, from an incident power density Σ is characterized by a coupling cross section σ, with units of area, such that P=σΣ. For front-door paths, σ is usually the effective aperture area of an antenna. The effective area peaks at the in-band frequency for the antenna, and falls off sharply with frequency as roughly f² above the in-band frequency and f⁴ below the in-band frequency. These are only very general relationships, very dependent upon mismatch effects and construction details. Therefore, to gain entry through an antenna, it is desirable to operate at the in-band frequency if it can be determined. The above discussion is for irradiation into the main lobe of the antenna. Radiating at random angles or into the side-lobes of an antenna tends to reduce the coupled power, often substantially.

Injection through back-door coupling paths has many complexities. There is, in general, a rapid variation of the coupling cross-section as a function of frequency due to the overlapping sets of coupling paths. Therefore, the coupling cross-section is often difficult to predict for a specific object without detailed testing, although properties averaged over frequency bands can be predicted. This makes ultra wide band (UWB) attacks (radiating a little energy into many frequencies) potentially more effective. At a distance L from a transmitting antenna with aperture a, the microwave beam diverges with angle λ/a. The power density of the microwave beam is S≈P₀(a/λL)², where P₀ and λ are the power and wavelength of the radiation. Holes and connectors on an irradiated object act as receiving dipole antennas with effective area σ=(λ/3)² when the antenna is matched. Due to increasing miniaturization, electronic components in a dense assembly are becoming better absorbers of microwaves. There is a high probability that one or several elements of a circuit inside a missile are placed near a small hole or connector on a missile casing at a distance less than λ that promotes impedance matching these antennas with the inner electronics. Therefore, the power received by an irradiated electronic system, P=σS≈0.1P₀(a/L)², is independent of λ. As a rule, losses of power transferring through back-door coupling to the vulnerable element do not exceed 10 dB, so the necessary radiation power for disruption of electronic devices is 0.01P₀(a/L)²>Pₜₕ, where Pₜₕ is a burnout or damage threshold of the element. Typical values of the catastrophic breakdown threshold Pₜₕ caused by 5 ns pulses on frequency 9.4 GHz for different types of mixer diodes (the most vulnerable element of receivers) are 1-2 W for standard Ni—GaAs, 2-4 W for Pd Schottky—GaAs, and 8-10 W for Ti—Mo—Au. In general, burnout threshold is Pₜₕ=1-35 W when microwave pulses τ=1-10 ns act on mixer diodes. (The threshold is inversely proportional to the pulse duration, Pₜₕ˜1/τ.) Considering a range of antenna diameters from 1 to 3 m, and a target range of 100 m to 1 km, mixer diodes can be destroyed at radiated powers of about 10 MW to about 1 GW.

One of the most attractive targets for high power microwave (HPM) generating devices is radar. However, most radar sets are designed with receiver protection devices (RPD), such as transmit/receive switches, to prevent near-field reflections of the radar transmitter from damaging the receiver through front-door coupling. RPDs could also protect against HPM. The RPD triggers and strongly attenuates incoming signals that exceed the damage threshold of downstream elements, such as mixers. The typical RPD allows an early spike to propagate through the system and then shorts the remainder of the pulse. The duration and intensity of the spike leakage is of crucial importance to being able to burn-out the more sensitive diodes of the downstream receiver. The technology of RPD-type devices used to limit pulse-semiconductors, gas plasma discharge devices, multi-pacting devices, and ferrite limiters, as well as hybrids and combinations of these devices—is very well developed. However, much fielded hardware typically uses pin-diodes. Because pin-diodes turn on after several tens of nanoseconds (e.g., 20-50 ns), there is no protection during this time before the diodes turn on. In some cases this technology is downgraded or removed in the field in order to facilitate system operation. It is clear that short, high-power pulses of narrow band radiation with defined frequency are preferred for suppression of operation of irradiated electronic devices through front-door coupling, whereas almost any radiation pulses (with any frequency and any pulse duration) can penetrate through back-door coupling but with less efficiency.

Once radiation penetrates into the interior of a target system, the susceptibility* of the small-scale semiconductor devices, which make up the interior electronics, becomes the important issue in HPM/UWB utility. Failures in semiconductor devices due to thermal effects occur when the temperature at a critical junction is raised above 600-800° Kelvin, resulting in changes in the semiconductor up to, and including, melting. Because the thermal energy diffuses through the semiconductor material, there are several failure regimes, depending upon the duration of the microwave pulse. If the time-scale is short compared to thermal diffusion times, the temperature increases in proportion to the deposited energy. It has been established experimentally that semiconductor junction damage depends only upon energy for pulse durations less than 100 ns, so that thermal diffusion can be neglected. Therefore, for pulses greater than 100 ns, thermal diffusion carries energy away from the junction. The general result is the Wunsch-Bell relation for the power to induce failure: P_{f}=Ct^{1/2}. The Wunsch-Bell relation is generally applicable because, although thermal conductivity and specific heat vary with temperature, the effects cancel out. Therefore, in the domain between about 100 ns and about 1 ms, the energy required to cause semiconductor junction failure scales as t^{1/2} and the power requirement scales at t^{-1/2}. For pulses longer than about 1 ms, a steady state occurs in which the rate of thermal diffusion equals the rate of energy deposition. Therefore, the temperature is proportional to power, resulting in a constant power requirement for failure. The energy requirement then scales as t. The consequence of these scaling relations is that the shortest pulses require the highest powers but the least energy. Conversely, the highest energy and lowest power is required for long pulses. Most HPM sources operate in the intermediate regime between 100 ns and 10 μsec. If energy is to be minimized in deployed weapons, the shorter pulses should be used, and if power is the limiting requirement, then longer pulse durations are most useful. * It is important in discussions of HPM DEW [Directed Energy Weapon] missions to understand effects nomenclature. Susceptibility occurs when a system or subsystem experiences degraded performance when exposed to an EM environment. Electromagnetic vulnerability is when this degradation is sufficient to compromise the mission. Survivability occurs when the system is able to perform a mission, even in a hostile environment, and lethality occurs when a target is incapable of performing its mission after being irradiated.

Damage is not the only mechanism to consider. Upset of digital circuits occurs when HPM couples to the circuit, is rectified at, for example, p-n junctions and produces a voltage equivalent to normal circuit operating voltage.

Currently there are three common approaches being pursued by others in developing electromagnetic munitions. In the first approach, a chemical explosive is used to drive what is termed a “magnetic flux compression generator.” In this approach, the chemical explosion forces a metal conductor to compress magnetic flux that was generated using a small “seed” electrical source. The resultant high voltage spike is used to power some type of narrowband microwave source, or a noise generator. This approach suffers from the use of high explosives; in addition to the electrical signal generated, considerable shrapnel is also a by-product, an issue that one wishes to avoid in non-lethal munitions: U.S. Pat. No. 6,477,932, which is incorporated by reference, shows an example of the first approach. In the second approach, an all electrical system, typically including a Marx generator and a pulse forming network, is used to tailor a high voltage electrical pulse to drive either a narrowband or wideband source. This approach suffers from the difficulty to make truly compact and lightweight sources using this technology. Also, the part count is inevitably large, and there are serious issues in terms of hardening such a munition to satisfy launch requirements. In the third approach, a ferroelectric shock line is used to generate a high voltage pulse. This approach, however, takes advantage of the piezoelectric property of certain dielectrics, which produce electrical pulses upon mechanical stress. This approach also suffers from a large part count, and there are serious issues pertaining to the hardening of a system using this technology.

Therefore, it is desirable to provide systems and methods that overcome the above and other problems. For munitions applications in particular, it is desirable to provide a single-shot electromagnetic pulse generating device capable of disrupting or destroying electronics that is simple, compact and reliable. The components of such a device should also be easy to integrate into a munitions shell, which may have severe volume constraints.

### BRIEF SUMMARY

The present invention provides systems and methods for generating high power, wideband microwave radiation pulses. A pulse generating device according to various embodiments of the present invention includes a capacitor as a primary electric energy store, a source of mechanical or chemical energy for modifying the capacitance of the capacitor, which then connects to a transmission line or pulse forming line (PFL) with many times increased electromagnetic energy, a switch and a broadband radiating element such as an antenna.

In certain aspects, a high voltage pulse and accordingly a high amount of electromagnetic energy is formed owing to decreasing the capacitance of an initially charged capacitor by dynamically changing a configuration of capacitor electrodes using mechanical work. The final configuration forms a transmission line, with the voltage and electric energy increased by the ratio of initial capacitance to final capacitance when the charge on the modifying capacitor is conserved. A switch connects opposite charged parts of the transmission line, and the resulting high voltage in the form of a pulse or multiple pulses propagates along the transmission line to a load (antenna) to generate one or more electromagnetic pulses.

In one aspect, a munitions device includes a capacitor configuration as the primary energy storage medium. In certain aspects, the final capacitor configuration fills up to the entire available volume within a munitions shell so as to provide the maximum possible capacitance value within that volume constraint. For the volume of a cylinder, for example, the initial capacitance corresponds to the topology that provides the maximum area of overlap of capacitor electrodes A and the minimum distance d between them, however configurations of the capacitor can be different. For example, the capacitor configuration can include numerous interleaved coaxial cylinders, or numerous parallel plates, or two parallel plates wound up in a cylindrical configuration. In a certain embodiment, all or a portion of the capacitor volume is filled with a material of high dielectric constant and high resistance to electrical breakdown to provide a further increase in the capacitance.

In another aspect, the initial capacitor configuration fills up to the entire available volume within a munitions shell so as to provide the maximum possible capacitance value within that volume constraint in order to accumulate the maximum electric energy. In one aspect, the final capacitor configuration is formed by separating one part of the device (e.g., munitions shell) from another part of the device.

In operation, mechanical or chemical energy is used to dynamically decrease the capacitance of the capacitor after it has fully charged, while maintaining a net charge on the plates, to thereby obtain voltage and electric energy multiplication. The applied mechanical or chemical energy may be implemented using any of a variety of mechanical force actuation systems, including for example, an explosive charge, an electromechanical biasing mechanism or the centrifugal force of a rotating munitions shell or other means for enabling mechanical work to alter the configuration of capacitor electrodes.

The capacitance can be decreased in different ways: for example, by increasing the distance between capacitor plates, or by reducing the area of overlap of the capacitor plates, or by dynamically decreasing the dielectric constant of a dielectric material between the capacitor plates, or by any combination of two or more of these ways.

According to one aspect, a system for generating a high power, wideband microwave radiation pulse includes a dipole formed by separating electrodes of a cylindrical capacitor due to their mutual axial motion from the initial configuration of an initially charged capacitor. When opposite charged electrodes are separated, a controlled switch or electric breakdown connects the electrodes leading to fast discharge of the capacitor in the form of a dipole antenna and high power radiation from this antenna. In this aspect, the final capacitor is simultaneously a pulse forming line, and radiator. The inner part of this device can be used for additional electrodes of the capacitor or can include other elements such as a power supply, radar, synchronizer, circuitry for controlling a switch initiated breakdown, etc. According to another aspect of the present invention, configurations of capacitor electrodes can be chosen so as to form a final capacitor as a bi-conical antenna when parts of the capacitor with different potentials are separated. Electrical breakdown between inner parts of the final capacitor leads to high power radiation of the bi-conical antenna.

According to another aspect, a high power pulse generation system is provided that typically includes a capacitor electrode configuration having an initial capacitance and a substantially constant charge, a first conduction element, a load element coupled with the first conduction element, a switch element coupled with the first conduction element, and a capacitance reduction mechanism configured to dynamically reduce the capacitance of the capacitor configuration, while maintaining the substantially constant charge on the capacitor configuration. In certain aspects, the capacitance reduction mechanism dynamically reduces the capacitance by: a) reducing an area of overlap of the capacitor electrodes, b) increasing a distance between the capacitor electrodes, c) reducing a dielectric permittivity between the capacitor electrodes or d) using any combination of a), b) and/or c). Upon reduction of the capacitance, a voltage of the capacitor is increased and a voltage pulse is generated, wherein the switch element couples one of a capacitor electrode or a second conduction element with the first conduction element so as to form a pulse forming line (PFL), and wherein the voltage pulse propagates along the PFL to the load element.

According to another aspect, a method is provided for generating a high power pulse in a delivery device. the method typically includes providing a capacitor electrode configuration coupled with a pulse forming line (PFL) in the munitions device, the capacitor configuration having an initial capacitance and a substantially constant charge, and dynamically reducing the capacitance of the capacitor electrode configuration, while maintaining the substantially constant charge on the capacitor electrode configuration, wherein upon reduction of the capacitance, a voltage of the capacitor electrode configuration is increased and a voltage pulse is generated on the PFL. In certain aspects, the delivery device includes one of an unmanned aerial vehicle (UAV), a missile, a rocket, or a munitions device.

Reference to the remaining portions of the specification, including the drawings and claims, will realize other features and advantages of the present invention. Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF THE DRAWINGS

FIG. 1 illustrates a side view of an electromagnetic munitions system including a voltage multiplication device according to an embodiment of the present invention. FIG. 1a shows an initial capacitor configuration including two groups of interleaved cylinder electrodes that form a capacitor; FIG. 1b shows a configuration after the electrodes have been separated to multiply the voltage (and electrical energy).

FIG. 2 illustrates a side view of an electromagnetic munitions system including a voltage multiplication system according to another embodiment. FIG. 2a shows an initial capacitor configuration including two groups of interleaved cylinder electrodes that form a capacitor with the maximum available volume in a missile or other delivery system in order to accumulate the maximum electric energy. FIG. 2b shows a configuration after the capacitor electrodes have been separated to multiply the voltage and electric energy. The final configuration of the capacitor is formed by separation of one part of the munitions shell from another. FIG. 2c shows the details of the telescoping center electrode driven by a small explosive charge.

FIGS. 3a and 3b show cross sections of two different configurations of alternating opposite charged electrodes: coaxial cylinders and parallel plate.

FIG. 4 shows voltage pulses (FIG. 4a) on a matched antenna and pulses of radiating electric field (FIG. 4b) when a switch connects opposite charged electrodes of a coaxial transmission line: a central electrode and a cylinder closest to it. FIGS. 4c and 4d also show a voltage pulse and radiated electric field, when rise time of the voltage pulse determined by a switch inductance and time of the voltage pulse propagation through the transmission line are commensurable.

FIG. 5 shows a voltage pulse (FIG. 5a) on electrodes of a matched antenna and pulses of radiating electric field (FIG. 5b), when a switch connects opposite charged cylinders closest to a central electrode.

FIG. 6 shows a tapered capacitor electrode configuration useful for capacitance reduction and voltage amplification according to one embodiment. FIG. 6 shows a capacitor configuration after separation of capacitor electrodes.

FIG. 7 shows another tapered capacitor electrode configuration useful for capacitance reduction and voltage amplification according to one embodiment. FIG. 7 shows a capacitor configuration after separation of capacitor electrodes.

FIG. 8 illustrates a side cross-sectional view of a simplified capacitor configuration with two parallel plates. FIG. 8a shows an initial capacitor configuration, and FIG. 8b shows a capacitor configuration after mechanical energy has separated the capacitor elements by spooling them on two parallel cylinders.

FIG. 9 illustrates a side view of another simplified capacitor configuration with two parallel plates. FIG. 9a shows an initial capacitor configuration, and FIG. 9b shows a capacitor configuration after separation of capacitor electrodes.

FIG. 10 illustrates another embodiment of capacitor electrode configuration useful for capacitance reduction and voltage amplification.

FIG. 11 illustrates an example waveform of output radiation.

FIG. 12 shows one useful antenna that includes a symmetric planar dipole that has “shoulders” in the form of two oppositely-placed circular sectors with central angles.

FIGS. 13 and 14 show examples of other useful antenna configurations connected with transmission lines formed as result of modification of initial capacitors.

FIG. 15 shows a parachute covered by foil that can be used as an additional parabolic antenna with a large aperture according to one embodiment.

FIG. 16 shows a transmission line with a pulsed twin-line antenna.

FIG. 17 shows a transmission line with a horn antenna-like structure.

FIG. 18 shows voltage pulses (FIG. 18a) on electrodes of an antenna with a transmission line with losses and pulses of radiating electric field (FIG. 18b), when a switch connects opposite charged electrodes of the line.

FIG. 19 shows that it is possible to match over a wide range with an antenna such as a tapered horn antenna.

FIG. 20 shows a typical section of receiver input circuit.

FIG. 21 shows a typical schematic of a receiver from the mixer input to the n^{th} cascade of an IF amplifier.

### DETAILED DESCRIPTION

### General Overview

The present invention provides electromagnetic pulse generating systems, devices and methods. A pulse generating device or system according to the present invention includes a capacitor as an electric energy storage medium, source of mechanical or chemical energy for modifying the initial capacitor to a transmission line or pulse forming line (PFL) with increased electromagnetic energy and voltage, a switch, and a broadband radiating element such as an antenna. In one aspect, such a device is implemented in a munitions shell or other delivery device. Although this document refers generally to voltage amplification devices and systems included in, or integrated with, a munitions device, it should be appreciated that the teachings of the present invention are applicable to voltage multiplications devices included in, or integrated with, other delivery devices such as a UAV and missiles or rockets or other delivery devices.

According to one embodiment, a pulse generating device includes a capacitor configuration as the primary electric energy storage medium. In certain aspects, the capacitor configuration, as will be discussed in more detail below, may include a coaxial cylinder configuration, a parallel plate configuration or a configuration of two parallel plates wound up into an interleaved cylinder configuration. Other useful capacitor configurations will be apparent to one of skill in the art.

According to one embodiment, one or more high voltage pulses are formed by dynamically changing the capacitance of the configuration of capacitor electrodes using mechanical work. In operation, mechanical or chemical energy is used to dynamically decrease the capacitance of the capacitor configuration after it has fully charged, while maintaining the net charge on the capacitor plates, to thereby obtain voltage and electric energy multiplication.

Operation of electromagnetic pulse generating systems according to embodiments of the present invention is based on transformation of mechanical or chemical energy to electromagnetic radiation by mechanically modifying a capacitor configuration, which is a primary electric energy store, to a transmission line with increased electric energy. A dielectric medium with permittivity ∈ separates opposite charged electrodes of a capacitor. When the dielectric medium has a sufficiently large resistivity ρ such that the characteristic time τ_{C}=∈ρ of self-discharge of the capacitor is much longer than the time τ, a charge q on the capacitor remains during this time τ. In certain aspects, where the device is incorporated in a missile or other munitions device, when τ_{C} is much longer than the time of a missile flight, it is possible to charge a capacitor before the flight from a power supply external to the missile. In this case it is not necessary to include a battery in the missile. In operation, an initial voltage Uᵢ of an initial capacitor configuration increases by a factor M=Cᵢ/C_{f} to a voltage U_{f} when an initial capacitor configuration having a capacitance Cᵢ mechanically changes to a final capacitor configuration having a capacitance C_{f}. The initial electrical energy Wᵢ=qUᵢ/2 also increases M times. In certain aspects, the final capacitor configuration forms a transmission line, which is coupled with a radiating antenna. When a switch connects opposite charged electrodes of the transmission line, voltage pulses propagate along the transmission line to an antenna to produce electromagnetic pulses, the duration of which depends on an inductance of the switch. Radiating efficiency depends on the spectrum of the voltage pulses as well as on an impedance and frequency band of the antenna.

For munitions applications where a size and volume constraint may be present, the final configuration should fill up to practically the entire available volume within the munitions shell so that a maximum possible capacitance is obtained to accumulate the maximum allowable electric energy. For the volume of a cylinder, for example, the maximum capacitance corresponds to the topology that provides the maximum area of overlap of capacitor electrodes A and the minimum distance d between them, whether the configuration includes parallel plates or interleaved cylinders or other configuration of plates. In one aspect, all or a portion of the capacitor volume is filled with a dielectric material of low conductivity and high resistance to electrical breakdown to avoid charge leakage. It is advantageous to use a dielectric with high permittivity, ∈, to provide the maximum capacitance and, therefore, the maximum accumulated electric energy.

For a parallel plate capacitor configuration, capacitance is generally expressed as C=∈A/d. Dynamically changing either the area, A, or changing the gap distance, d, and/or changing the permittivity of the dielectric medium in the gap results in a change in the capacitance. Therefore, the capacitance can be reduced by mechanical means in different ways: either reducing the area, A, or increasing the gap distance, d, or decreasing the permittivity ∈ (for example, by removing all or a portion of the dielectric material from the capacitor). When the charge of the capacitor is kept constant, these methods lead to conversion of the mechanical energy into electrical energy. Similarly, for a coaxial cylinder capacitor configuration, capacitance is generally expressed as C=∈l ln R_{b}/Rₐ), where l is the length of the cylinder, and R_{b} and Rₐ are the radii of the outer and inner cylinders, respectively. As can be seen, either reducing the overall (overlapping) length l or increasing the separation between R_{b} and Rₐ (increase R_{b} and/or decrease Rₐ), and/or decreasing the permittivity of the dielectric medium reduces the capacitance of an interleaved cylinder configuration.

Various kinds of energy generating mechanisms can be used to decrease the capacitance (e.g., to increase the gap distance, d, between capacitor plates and/or decrease the area of overlap of capacitor electrodes). For example, energy for modification of capacitor configurations can be applied using a small amount of explosives, using a hydraulic actuation mechanism, or using an electric motor. For example, energy may be applied to separate the electrodes of a parallel plate capacitor in a direction normal to the plates (increase d) and/or separate the plates in a direction parallel to the plates (e.g., reduce area of overlap), and/or remove dielectric material from the capacitor. Similarly, in an interleaved cylinder arrangement, energy may be applied to separate the capacitor elements or cylinders in a direction parallel to the axis of these electrodes (e.g., reduce area of overlap).

### Configurations of Electromagnetic Devices

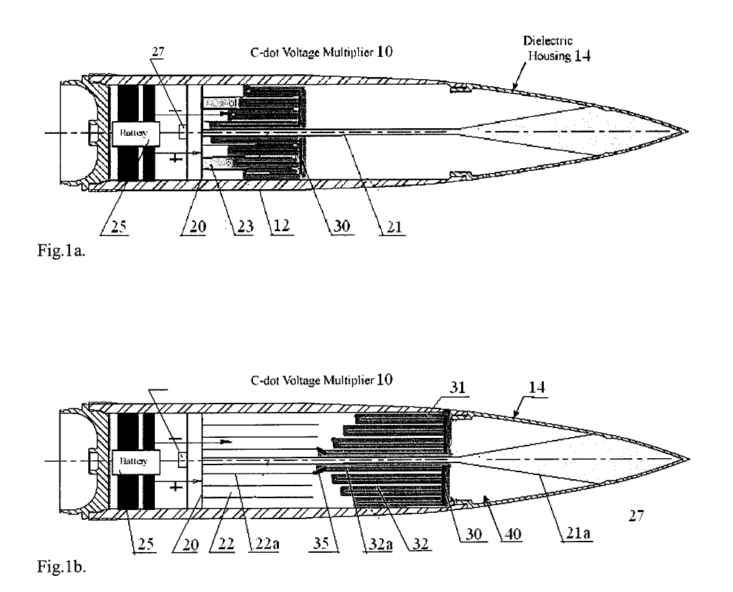

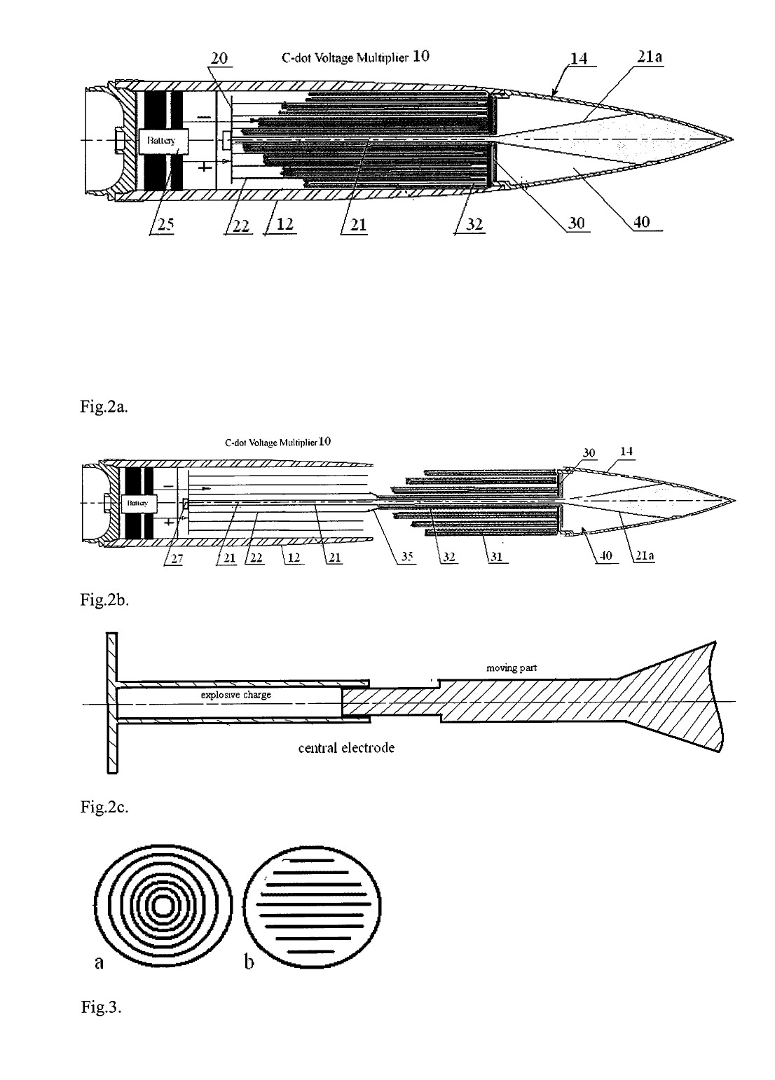

FIGS. 1 and 2 illustrates side views of munitions including a pulse generation system. FIG. 1 shows one embodiment where a final configuration of a capacitor fills all the available volume of a missile or other delivery device, and FIG. 2 shows an embodiment where an initial capacitor fills all available volume of the device, and a final configuration of this capacitor is formed by separation of one part of the device from another. One reason to fill the maximum volume by an initial capacitor is to store the maximum initial energy.

In one embodiment, munitions system 10 includes a metal case 12 and dielectric housing head 14 enclosing a capacitor configured with electrodes 30 (covered with dielectric 31) and 20, a battery 25, explosive charge 23 and a controlled (for example, by timer) igniting charge 27. FIG. 1a shows an initial capacitor configuration including two groups of interleaved metal cylinders, 20 and 30, charged by a battery 25. Ignition device 27 provides a pulse for ignition of explosive charge 23, placed in one of free spaces between the electrode 20 and dielectric 31 covering the electrode 30, that pushes the electrode 30 along the munitions case 12 toward dielectric housing 14. FIG. 1b shows a final position of the capacitor, the inner electrodes of which (e.g., 20a, 30a and the central electrode 21) form a transmission line discharged through a switch 35, whereas surfaces 40a and 40b form an antenna 40.

The capacitor configuration includes, at the left-hand side, a plurality of first capacitor electrode elements 22 (e.g., concentric metal cylinders) connected to a metal electrode plate 20. Voltage source 25 is used to charge the capacitor structure. The capacitor configuration also includes, on the right hand side, a plurality of second capacitor electrode elements 32 (e.g., concentric metal cylinders) connected to a second metal plate 30. In the initial capacitor configuration (FIGS. 1a and 2a), the cylinders 22 are enclosed into the cylinders 32 so that they overlap each other, but without electrical contact between them. The more overlap area, the more initial capacitance and the more initial accumulated energy. Cylindrical gaps between the electrodes are filled by a dielectric medium. The initial capacitor is charged by battery 25 or other power supply. Power supply 25 need not be included in the munitions device 10; a separate battery or other source element that provides electrical energy may be used to charge the capacitor structure (e.g., using a rectifier) and then disconnected prior to launch of munitions device 10 when a charge can be saved in during flight time. When present, the battery is disconnected from the capacitor when an explosive charge 23 ignites by a controlled device (or a timer) 27, and the opposite charged electrodes 22 and 32 begin separation, or motion in opposite directions. Voltage between electrodes 22 and 32 increases as their mutual overlapped area decreases, while maintaining electrical charge received from the battery 25. Axial lengths of overlapped electrodes 22 and 32 are chosen so that in the final position (FIGS. 1b and 2b), when these electrodes are finally separated, their inner facings, electrodes 22a and 32a together with the central electrode 21 form a transmission line which is coupled to an antenna 40. With such a configuration, the maximum electric field is in the gap between electrodes 22a and 32a, which contains a switch 35 (for example, a triggered solid dielectric switch or breakdown in this gap). One of the antenna electrodes includes a conical electrode 21a coupled with the central electrode 21, which is connected with all faces 22 through plate 20. Another antenna electrode includes the electrode 30, which connects all opposite charged faces 24. The central hole in plate 30 is the output end of a coaxial transmission line.

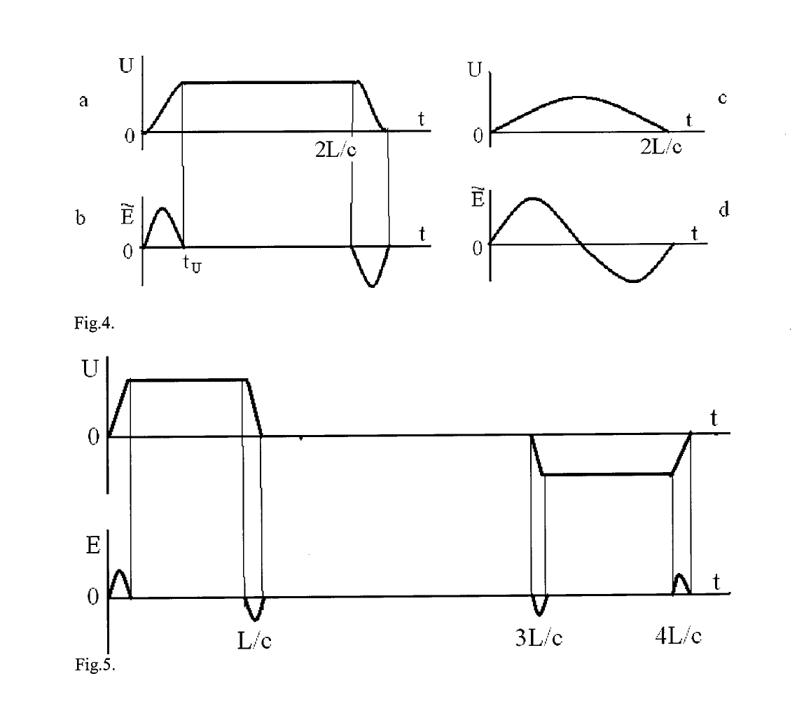

The antenna 40 is formed by the electrode 30 and a conical electrode 21a connected with the central electrode 21. This forms a modified wide band bi-conical antenna. In the case shown in FIG. 2, the antenna configuration 40 is formed by electrodes 30 and 21a together with forming of the final configuration of the capacitor, that is, when the electrode 30 (together with electrodes 32) occupies its final position. It can also be realized with the telescoping inner electrode 21, which parts (FIG. 2c) can move relative to each other while maintaining electrical contact between them. One of the parts may include a mechanism (for example, explosive charge with controlled time of ignition (trigger element 27)) for separation of one part of the capacitor from another. When the switch 35 connects the electrodes 22a and 32a (or 32a and 21), voltage pulses forming in the transmission line, are radiated by the antenna 40 in form of electromagnetic pulses determined by parameters of the switch 35 and the transmission line. Examples of radiated waveforms are shown in FIGS. 4 and 5.

In operation, initially charged electrodes of the initial capacitor are mechanically separated forming a final capacitor configuration with increased voltage between the electrodes. Increasing the voltage is due to decreasing the area of overlapping electrodes 22 and 32. When a switch 35 connects these electrodes 22a and 32a or 32a and 21, the final capacitor configuration operates as a coaxial transmission line loaded on an antenna (to avoid breakdown between other electrodes, overlapping electrode area should decrease with distance from the switch). When the switch 35 connects electrodes, a voltage pulse with duration τ=2L/c\sqrt{∈} appears on the electrodes of a matched antenna with rise time determined by switch inductance. Here L is a length of the cylinder 32a and c is the light velocity. The rise time determines duration of electromagnetic pulses radiated by the antenna 40 through the dielectric housing 14. When the switch 35 connects electrodes 32a and 22a, the first voltage pulse with duration τ=L/c\sqrt{∈} has a rise time t_{U} determined by switch inductance, and the second voltage pulse is from t₁=3L/c\sqrt{∈} to t₂=4L/c\sqrt{∈} (FIG. 4a) where L is a length of each cylinder, 32a and 22a. When the cylinders are short so that t_{U} is commensurable with τ, voltage pulses and the radiated field look as in FIGS. 5a and 5b (when the switch connects cylinders 21 and 32a).

In certain aspects, the capacitor volume is filled with a dielectric material to provide an increased capacitance and increased stored electrical energy. In general, any dielectric material with high electrical resistivity and high resistance to electrical breakdown may be used, although it is advantageous to use a material having a high dielectric constant. Air gaps in the region of overlapping electrodes and at their point of disconnection should be excluded in order to avoid breakdown through air and avoid decrease of the initial capacitance. It is useful to fill air gaps with a fluid (e.g., liquid or gas) dielectric (desirably with the same or similar permittivity as a solid dielectric, if used, to avoid jumps of electric field at boundaries between different media). Useful dielectric materials are sulfur hexafluoride, (SF₆) gas, Teflon, polyethylene, and insulating oil.

Although the above description of FIGS. 1 and 2 discuss capacitor electrodes having a coaxial structure (e.g., interleaved metal cylinders as shown in FIG. 3a), it should be appreciated that the capacitor electrode elements may be other configurations, for example, in form of planar structures as shown in FIG. 3b. It should also be appreciated that the sizes, dimensions and numbers of separate electrode plates or cylinders may vary depending upon the design parameters of the system, e.g., internal munitions shell dimensions.

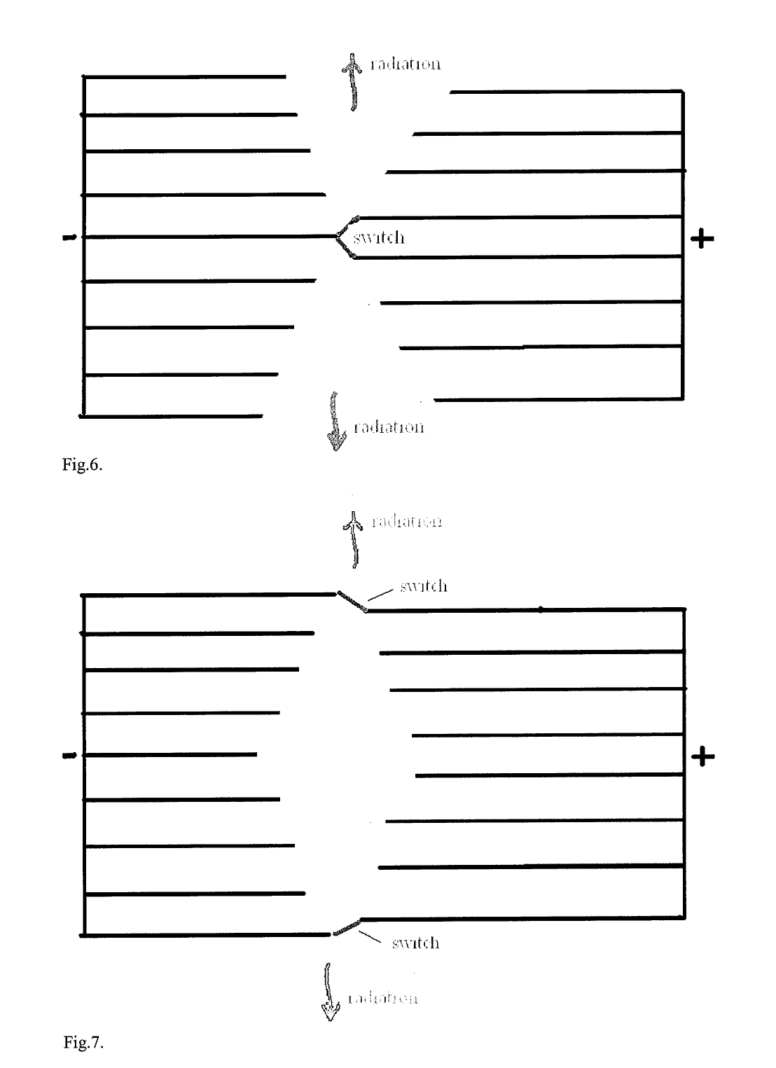

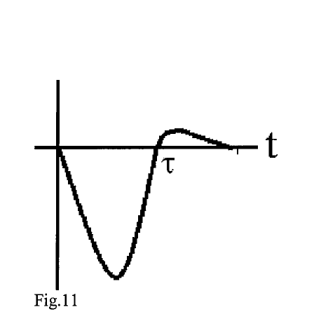

FIGS. 6-10 show examples of other various capacitor configurations according to various embodiments of the present invention. For example, FIG. 6 shows a side cross-sectional view of a tapered capacitor electrode configuration useful for capacitance reduction and voltage amplification according to one embodiment. The configuration shown in FIG. 6 is similar to that shown in FIG. 1, however, the cylindrical electrode elements are tapered (length of electrodes increases) toward the inside. FIG. 6 shows a capacitor configuration after mechanical energy has separated the capacitor elements. When opposite charged electrodes are selected, the maximum voltage appears between them that leads to breakdown between opposite charged facings of minimum spacing through a dielectric covering on one of electrodes. This breakdown can serve as a switch. Discharge of the capacitor through the resistance and inductance of the switch leads to rapidly attenuated oscillations of this LCR-type circuit (FIG. 11) that generate radiation by the bi-conical antenna formed by separated electrodes.

FIG. 7 shows a final capacitor configuration according to another embodiment after mechanical energy has separated the capacitor elements of a configuration. As shown in FIG. 7, the capacitor configuration includes cylindrical electrode elements that are tapered (length of electrodes increases) toward the outside. In the tapered configuration shown in FIG. 7, the charge on the plates migrates toward the outer portions as the plates are being separated, thereby concentrating the electrical energy at the outer portion of the capacitor configuration. Unlike a device shown in FIG. 6, a final capacitor configuration in FIG. 7 forms a dipole antenna when a switch connects opposite charged outer electrodes. An example of a resulting radiation pulse is shown in FIG. 11

FIG. 8 illustrates a side cross-sectional view of a simplified capacitor configuration with two parallel plates. FIG. 8a shows an initial capacitor configuration, and FIG. 8b shows a capacitor configuration after mechanical energy has separated the capacitor elements. The plates are coupled to conductive winding elements that are coupled to an actuator mechanism. After the capacitor configuration is charged with a net charge (e.g., + and − as shown) in the initial configuration of FIG. 8a, the actuation mechanism is triggered to wind the plates (see arrows in FIG. 8a) and reduce the area of overlap of the plates, thereby reducing capacitance and increasing voltage. The actuation mechanism may include an electric motor coupled to each winding element. In certain aspects, the winding elements comprise the PFL.

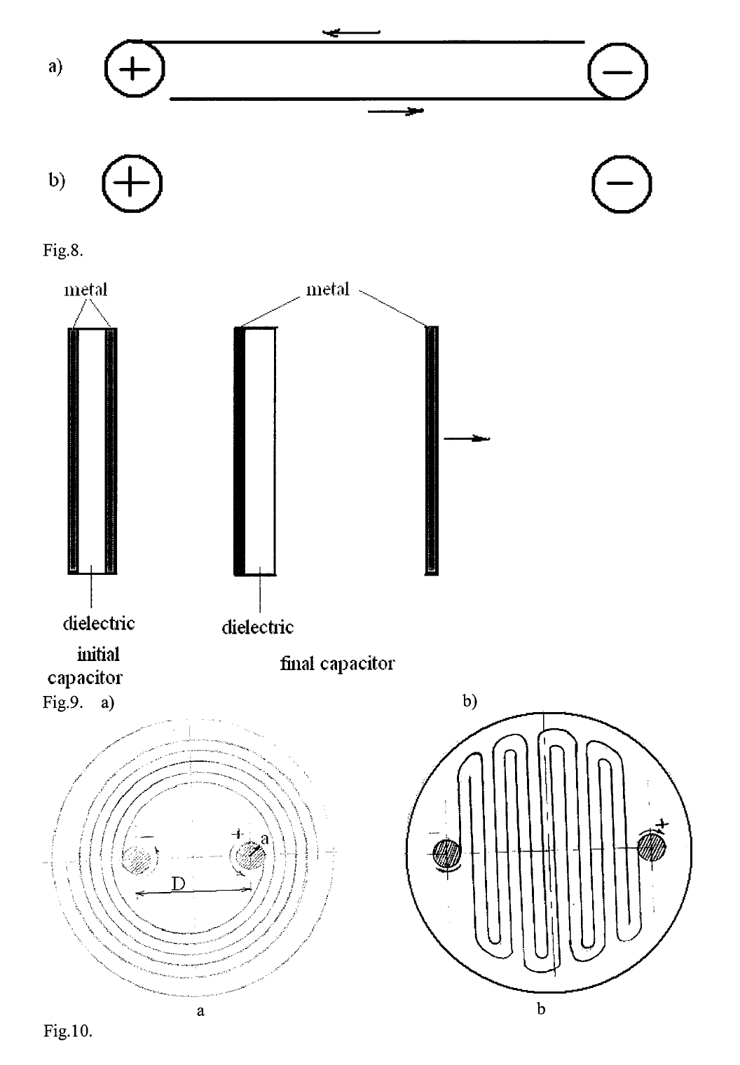

FIG. 9 illustrates a side view of another simplified capacitor configuration with two parallel plates. FIG. 9a shows an initial capacitor configuration, and FIG. 9b shows a capacitor configuration after mechanical energy has separated the capacitor elements. As shown, the plates are separated in a direction normal to the plane defined by the parallel plates. In this manner, the gap distance, d, between the plates is increased to reduce capacitance. An optional dielectric material, as shown, may be included to increase the initial capacitance of the capacitor configuration.

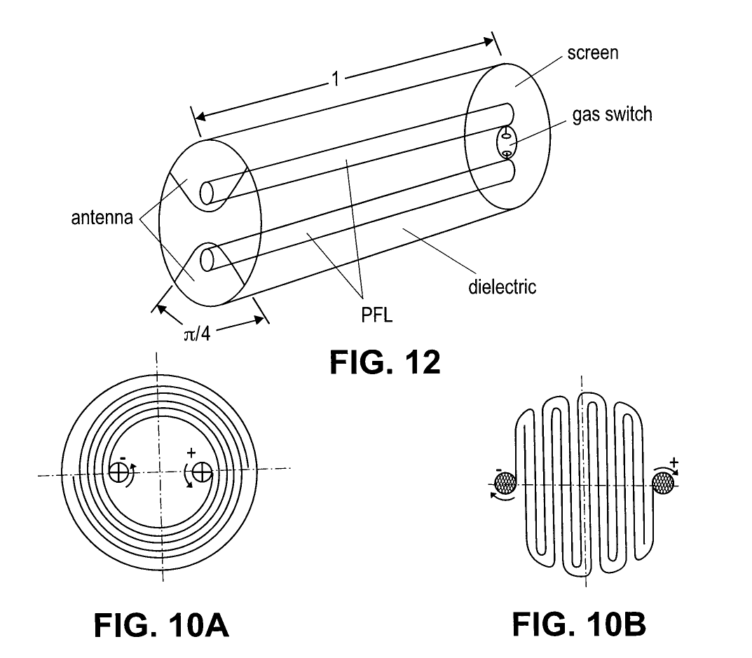

Another embodiment of capacitor electrode configuration useful for capacitance reduction and voltage amplification is shown on FIG. 10. In this embodiment, capacitor electrodes are placed onto, or coupled with, conductive spools or winding elements and wound up in a cylindrical configuration to provide the maximum length for two parallel electrodes in a given diameter. In one aspect, as shown, a solid dielectric cylinder (e.g., Teflon or other polymer having a suitable dielectric constant) is used to support the two spooling conductors and guide the motion of the plates through guide channels, in addition to providing electrical insulation. After the capacitor configuration is charged with a net charge (e.g., + and − as shown) in the initial configuration of FIG. 10, an actuation mechanism is triggered to wind the electrodes (see arrows in FIG. 10) and reduce their overlapped area, thereby reducing capacitance and increasing voltage. The actuation mechanism may include an electric motor coupled to each winding element. The final capacitor modified to a parallel wire transmission line or PFL is shown in FIG. 12. Examples of different configurations of an initial capacitor filling a cylindrical volume are shown in FIG. 10a and FIG. 10b. Such different configurations allow one to choose the most convenient version in order to provide available radii a of parallel wires and distance D between them in a final capacitor configuration that determines the impedance of the transmission line. For example, the configuration in FIG. 10a is convenient to provide small distance D between wires of the transmission line, whereas the configuration in FIG. 10b is more convenient to provide a greater distance D. When the switch connects the opposite charged electrodes of the transmission line (FIG. 12), the antenna radiates pulses shown in FIG. 4a (for a case, when rise time t_{U} determined by switch inductance is less than time of propagating the voltage pulse along the transmission), or FIG. 4d (for a case, t_{U} is congruous with τ).

In certain aspects, the stored energy and, accordingly, the energy of the radiated pulse generated by the various capacitor configurations can be increased if a dielectric is used that has a large dielectric constant and that is also highly resistant to breakdown. It also is important to avoid breakdown during the spooling time, when the shortening length of electrodes leads to an increase in the voltage.

A trigger element is included, in certain aspects, to control actuation of the capacitance reduction mechanism at an appropriate time. For example, for a wound up capacitor configuration as shown in FIG. 10, the trigger element would control spooling of the capacitor plates, and for a capacitor configuration as shown in FIGS. 1 and 2, the trigger element 27 would control the element or mechanism that separates the interleaved capacitor plates. A trigger element, in certain aspects, includes one or more of a pressure sensor and/or altimeter, an accelerometer, or a timer. Other useful trigger elements might include a proximity sensor, a turn counter and an automatic target recognition sensor.

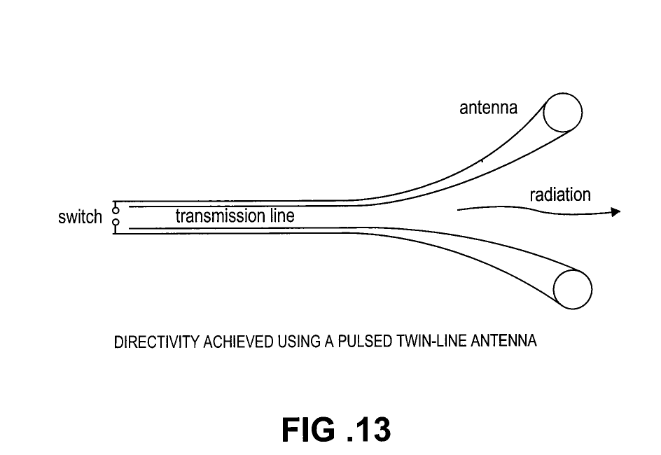

FIG. 13 illustrates another embodiment of the present invention, wherein the gap distance, d, is altered to provide voltage amplification. The motion of the capacitor plate 22 is driven by gas released from a high-pressure plenum 15 through a valve 16. The static capacitor plate 20 is part of the housing 12. The electrode 22 is separated from the other electrode 20 by an insulator 31. The system operation begins with the charging of plate 22 by a lead with a battery 25, which then disconnects. The valve 16 opens responsive to a command signal received from a trigger source, e.g., an external pressure sensor and/or altimeter, an accelerometer, a timer, etc. The gas exerts a high pressure on plate 22, propelling it along a chamber lined with dielectric 31. As the plate 22 reaches high voltage at the end of the chamber, due to the drop in capacitance, the spike stabber 24 breaks the dielectric switch 35. This closes the switch, connecting the high-voltage charged plate to the antenna 40.

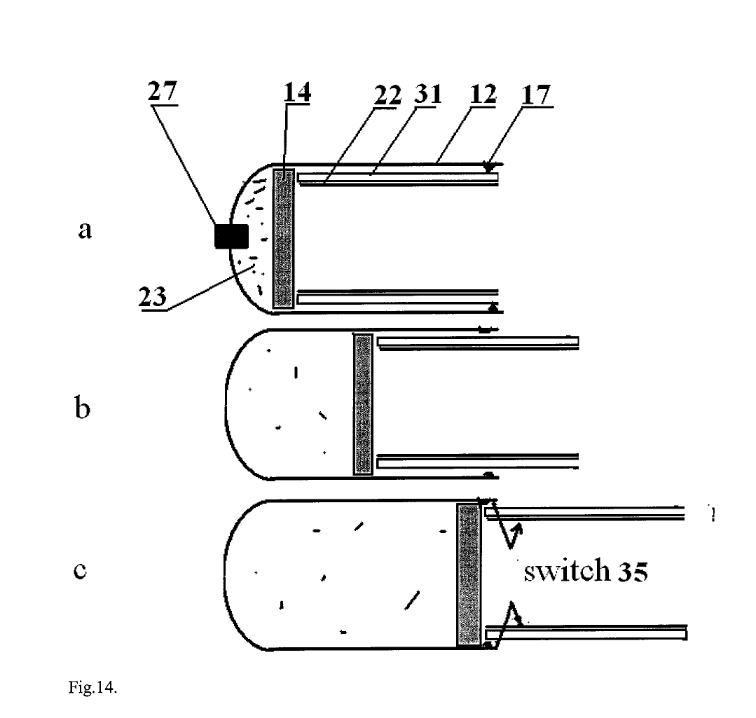

FIG. 14 illustrates a side cross-sectional view of a simplified capacitor configuration. An initial capacitor FIG. 14a with previously charged cylindrical electrodes, an electrode 12, which is a part of a missile case or other device, and an inner electrode 22 separated from 12 by a dielectric plunger 14 and dielectric cylinder 31. Between a metal face of the missile and the plunger 14, an explosive charge 23 is placed as it is shown in an initial configuration (FIG. 14a). When a controlled igniter 27 ignites or initiates the explosive charge 23, the plunger 14 pushes out the inner electrode 22, FIG. 14b, decreasing capacitance and increasing voltage, and in a moment, when electrodes are separated, a switch 35 connects the ends of electrodes (FIG. 14c) and radiation ensues. In certain aspects, a switch is implemented using a triggered solid dielectric switch or breakdown through a dielectric sleeve (a dielectric plunger 14 together with a dielectric sleeve 31 is stopped by a constriction 17). FIG. 11 shows an example of an output radiation waveform.

### Antennas

In FIGS. 1 and 2 a modified bi-conical antenna is shown. It is evident that a conical horn antenna, spiral antenna, and other types are available to be coupled with a transmission line. Antenna choice depends on impedance matching with the transmission line at the radiation frequencies. As is shown above, intensity of radiation, which is incident at a target, is proportional to the antenna aperture a. To concentrate the power on a target, radiated by any kind of antenna, a parachute covered by foil can be used as an additional antenna with large aperture as shown in FIG. 15.

In certain aspects, the voltage pulse (e.g., a short video-pulse) is generated in the PFL as a result of a short-circuited line on one end, and a matched load (e.g., antenna) on the other end. Shorting of the line upstream before the completion of the topological transformation of the capacitor can be achieved using a switch, such as a gas switch, that is connected to the end of the PFL. The time of breakdown of a gas switch is determined by the moment that the voltage on the charged line exceeds the switch's breakdown threshold. This time can be controlled with high precision. The pulse duration and center frequency of the radiation spectrum is determined by the properties of the switch and the PFL. Gas switches, for example, can be switched in about 1 ns (See, e.g., G. A. Mesyats, “Generation of High Power Nanosecond Pulses,” (in Russian) (Sov. Radio, Moscow, Soviet Union, 1974), p. 200). A length of the line of about 10 cm corresponds to a pulse duration of about 1 ns. In certain aspects, the PFL, together with the antenna and the gas switch, is immersed in a dielectric with high resistance to electrical breakdown.

An antenna with impedance of about 60πΩ matched to the PFL over a wide frequency range allows for the radiation of practically the entire energy accumulated in the line during one period of the basic oscillation; that is, in a time no greater than 1 ns; the presence of high odd harmonics in the pulse spectrum leads to steep slopes of the pulses. An example waveform of output radiation is shown in FIG. 11.

According to one aspect, one useful antenna as shown in FIG. 12 includes a symmetric planar dipole that has “shoulders” in the form of two oppositely-placed circular sectors with central angles π/4 (see, e.g., Y. T. Lo and S. W. Lee, Eds., Antenna Handbook (Ch.2) (Van Nostrand Reinhold, New York, N.Y., 1988)). In order to direct the isotropic radiation of the dipole to the forward semi-sphere of free space ahead of the munitions shell, a metal screen with diameter equal to the transverse dimension of the device is placed behind the antenna a distance 10 cm.

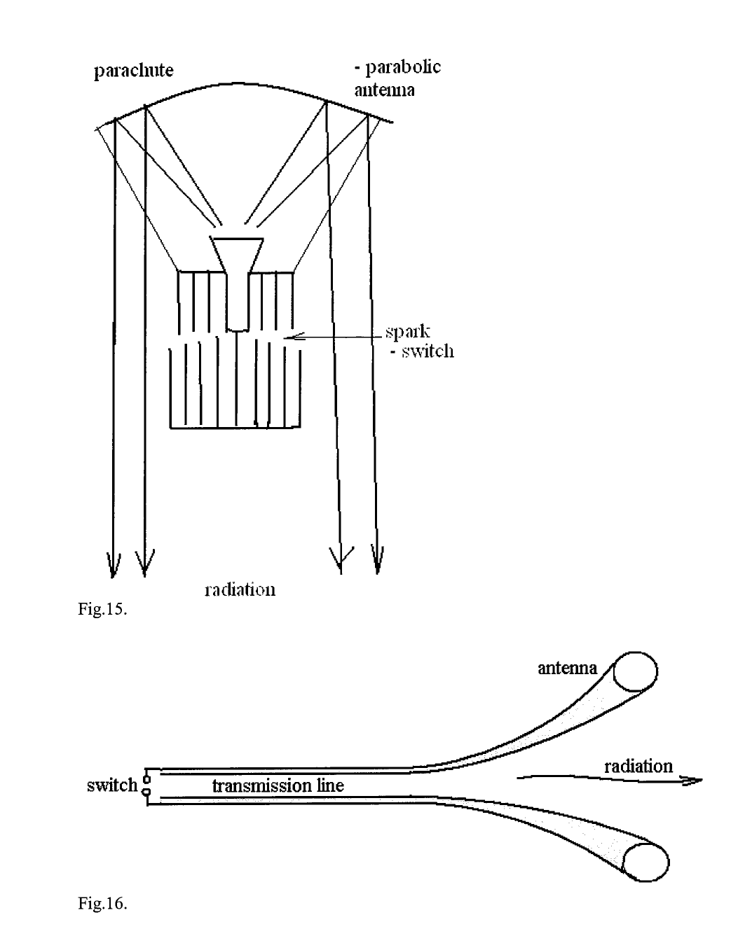

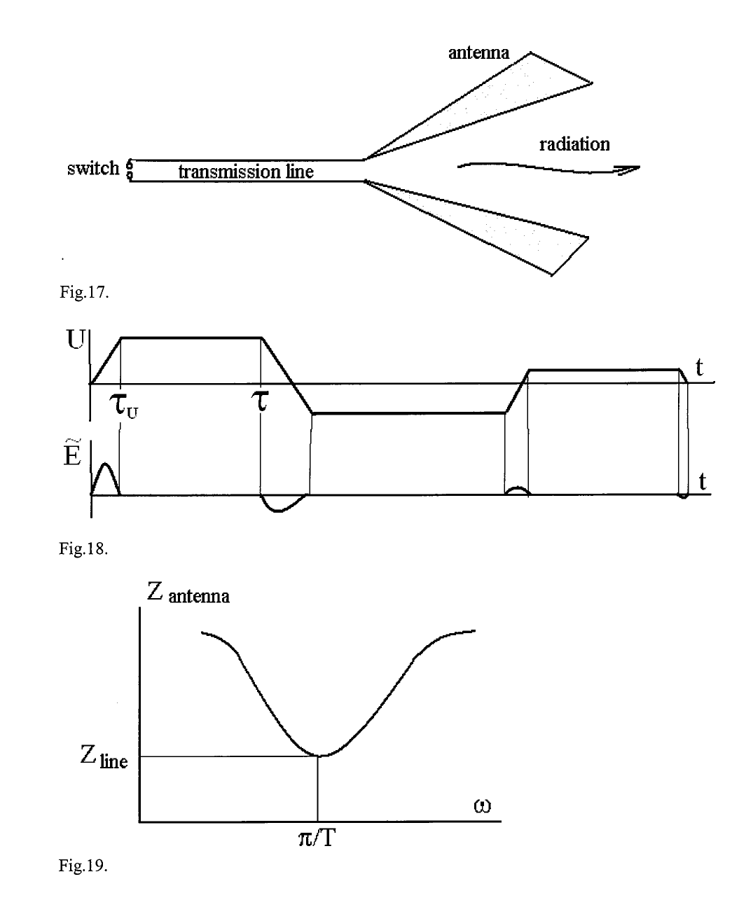

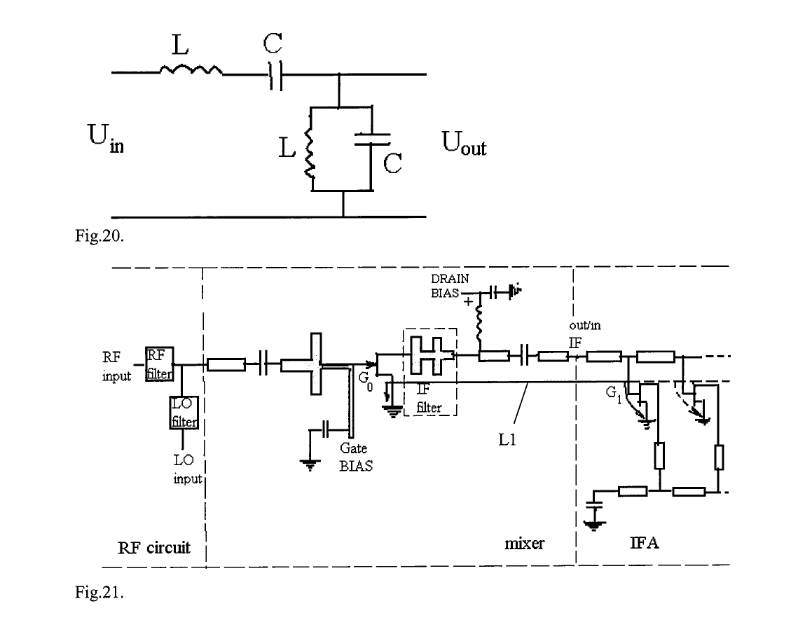

FIGS. 16 and 17 show examples of other useful antenna configurations. For example, if installation of the metal screen shown in FIG. 12 is complicated or undesired, radiation directivity can be provided using an antenna such a pulsed twin-line antenna without a metal screen as shown in FIG. 16 or a horn antenna as shown in FIG. 17 In general, other useful antenna structures include dipole antennas, spiral antennas, helical antennas, TEM horn antennas, bi-conics antennas, Impulse Radiating Antennas (IRAs), and others as would be apparent to one skilled in the art.

When the time of signal propagation τ in the transmission line with losses is much greater than the closing time τ_{U} of a switch, τ=L\sqrt{∈}/c>>τ_{U}, and the line is mismatched with antenna, the transients associated with the discharge of the line is shown in FIG. 18.

When τ˜τ_{U}, the basic frequency of the radiation ω≈π/τ, and the output will be rapidly attenuating when the antenna is matched to this frequency. It is not possible to radiate all of the accumulated energy W=CU²/2 during one period because the antenna is matched at one frequency, whereas the spectrum of a short pulse signal is broad; however it is possible to match over a wide range with an antenna such as a tapered horn antenna as is shown in FIG. 19. FIG. 12 shows that the main part of the accumulated energy will be radiated during a half period, although to radiate the total energy during one period is difficulty if not impossible because of the wide spectrum of the short signal, which is greater than the region of the proper matching of the antenna with the transmission line.

As above, power density incident at a target is proportional to antenna aperture a. To concentrate the power on a target, radiated by any kind of antenna, a parachute covered by foil can be used as an additional parabolic antenna with large aperture as shown in FIG. 15.

### EXAMPLES

As an example, with reference to the capacitor configuration shown in FIG. 3, assume that the dielectric between the plates is Teflon or polyethylene with a dielectric constant ∈=2.1, the distance between plates d=2.5 mm and the dimension along cylinder axis l=100 mm. If the plates are wound so that the length of each plate is 2.8 m, the area of the plates is 0.28 m² and the capacitance is equal to

$${C}_{0} = \frac{ɛ A}{d} ∼ 2 nF .$$

The electric field threshold for breakdown of polyethylene is about 60 kV/mm, so the 2.5-mm gap can support about 150 kV. Thus, for example, charging the capacitor to 1 kV and spooling the plates to reduce the capacitance by a factor of about 150 would give about 150 kV for switching out to a load.

The configurations of the capacitor plates can be different from the design shown in FIG. 6; one goal is to provide the maximal length for two parallel electrodes. In a munitions shell, for example, the capacitor can be charged up to U₀=1.2 kV using an ordinary rectifier directly before inserting the shell into the launching barrel. The accumulated electrical energy in the initial capacitor is thus W₀=CU₀²/2=0.0024 J.

As a PFL, a two-wire transmission line with line impedance provides a good match with the load, e.g., transmitting antenna, downstream. The other end of the line is short-circuited. Such a line, which includes two cylindrical wires with radius a and distance between centers D has impedance

$$ρ = \frac{120}{\sqrt{ɛ}} ln ( \frac{D}{2 a} + \sqrt{{( \frac{D}{2 a} )}^{2} - 1} ) = 60 π Ω ,$$

when D/a=12 (see, e.g., Y. T. Lo and S. W. Lee, Eds., Antenna Handbook (Ch.2) (Van Nostrand Reinhold, New York, N.Y., 1988)). The capacitance of this line with length l=10 cm is

$${C}_{l} = \frac{π {ɛɛ}_{0} l}{ln ( \frac{D}{a} - 1 )} \approx 2. \underline{4} pF .$$

### (See, e.g., B. M. Yavorski and A. A. Detlaf, Handbook on Physics (in Russian) (GIFML, Moscow, Soviet Union, 1963), p. 346.)

Once the shell is in the vicinity of a target, a trigger initiates a process of the transforming the topology of the capacitor to reduce capacitance and increase voltage. In this example, the transformation can be accomplished by spooling metal strips that are the electrodes of the capacitor, rotating on axes O₁ and O₂ with initial radii 0.4 cm (FIG. 12). These axes coincide with the axes of the PFL. The thickness of the plates should be about 40 μm in order to spool 2.8 m electrodes into a cylinder with radius 4 mm.

When the capacitance is decreased as a result of the transformation, the electrical energy increases by the ratio of the voltages. For example, if the capacitance changes from Cᵢ=C₀=2 nF to C_{f}=Cₗ=2.4 pF, the line will be charged to voltage

$${U}_{l} = \frac{{C}_{0}}{{C}_{l}} {U}_{0} \approx 1.0 MV ,$$

and the electrical energy increases about 830 times, thereby yielding about 1.2 J. The increase in the electrical energy is attributed to the input of mechanical work against Coulomb's forces during the time of the kinematic transformation of the initial capacitor topology to the final capacitor topology. The maximal force is no greater than about 400 N. The use of silicon grease or other lubricant in the channel decreases the friction force during spooling to a negligible value.

A way to disrupt elements of radio-receivers is to influence the channel corresponding to the intermediate frequency (IF). Consider a typical schematic of a receiver from the mixer input to the nth cascade of an IF amplifier as shown in FIG. 21. (See, e.g., K. Chang, Microwave Solid-State Circuits and Applications (J. Wiley & Sons, New York, N.Y., 1994)).

One typical aspect of the input part of microwave receivers is the use of a distributed system of grounding the microwave circuits and centered grounding in IF and low frequency circuits (see, e.g., J. L. N. Violette, D. R. J. White, M. F. Violette, Eds., Electromagnetic Compatibility Van Nostrand Reinhold, New York, N.Y., 1987)). Therefore, points of grounding of sensitive elements of the mixer and transistors of first IF cascades are placed with a sufficient separation. The line L1 in FIG. 21 comprises the ground G₀, output circuit of mixer, input IF cascade, ground G₁(G₂, . . . Gₙ) and occupies a large area, thereby acting as an effective magnet antenna.

The RF-IF circuits are typically placed in a single screened case or structure, which provides effective suppression of external high frequency fields. However, as a rule, magnetic shielding is typically not applied; therefore IF circuits are vulnerable to magnetic fields, which effectively interact with the parasitic loop antenna formed (as described above). The area of the region bounded by line L1 in FIG. 21 is greater than areas bounded by other contours. There is little resistance for the currents that are excited by the video-pulse, and this contour is loaded on the output circuit of sensitive element of the mixer. These features suggest that a quasistatic magnetic field could impact the device with high efficiency.

The use of a balanced mixer or semiconductor diodes as sensitive elements of the mixer does not change the aforementioned mechanism describing the effects of the RF on the mixer.

All publications, patents, patent applications and other references cited herein are each hereby incorporated by reference.

While the invention has been described by way of example and in terms of the specific embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A high power pulse generation system, comprising:
a capacitor electrode configuration having an initial capacitance and a substantially constant charge;
a first conduction element;
a load element coupled with the first conduction element;
a switch element coupled with the first conduction element; and
a capacitance reduction mechanism configured to dynamically reduce the capacitance of the capacitor configuration, while maintaining the substantially constant charge on the capacitor configuration, by: a) reducing an area of overlap of the capacitor electrodes, b) increasing a distance between the capacitor electrodes, c) reducing a dielectric permittivity between the capacitor electrodes or d) using any combination of a), b) and/or c);
wherein upon reduction of the capacitance, a voltage of the capacitor is increased and a voltage pulse is generated, wherein the switch element couples one of a capacitor electrode or a second conduction element with the first conduction element so as to form a pulse forming line (PFL), and wherein the voltage pulse propagates along the PFL to the load element.

2. The system of claim 1, wherein the capacitor electrode configuration includes a plurality of interleaved coaxial cylinders or plates.

3. The system of claim 1, wherein the capacitor electrode configuration includes a plurality of interleaved planar plates.

4. The system of claim 1, wherein the capacitor electrode configuration includes two planar plates wound up into an interleaved cylindrical electrode configuration around two conducting rods, and wherein the switch element couples the two rods to form a parallel wire PFL.

5. The system of claim 1, wherein reducing the dielectric permittivity includes removing dielectric material from between the electrodes.

6. The system of claim 1, wherein the switch element comprises a breakdown switch.

7. The system of claim 1, further including a trigger element configured to control operation of said capacitance reduction mechanism.

8. The system of claim 7, wherein the trigger element includes one or more of an altimeter, a pressure sensor, an accelerometer, a timer, a proximity sensor, a turn counter, and an automatic target recognition sensor.

9. The system of claim 1, wherein the load element includes antenna.

10. The system of claim 8, wherein the antenna comprises one of a dipole antenna, a spiral antenna, a helical antenna, a TEM horn antenna, a biconics antenna, and an Impulse Radiating Antenna (IRA).

11. The system of claim 1, wherein the capacitance reduction mechanism includes one of an explosive charge, a hydraulic actuator coupled with the capacitor electrode configuration or an electric motor coupled with the capacitor electrode configuration.

12. The system of claim 1, wherein the capacitor electrode configuration includes a plurality of interleaved conduction electrodes, and wherein the capacitance reduction mechanism is configured to reduce the area of overlap of said interleaved conduction electrodes.

13. The system of claim 1, wherein the capacitor electrode configuration includes a pair of planar conduction electrodes wound into an interleaved cylindrical configuration, and wherein the capacitance reduction mechanism includes winding elements configured to wind up the conduction electrodes to reduce the area of overlap of the conduction electrodes.

14. The system of claim 13, wherein the winding elements are conductive.

15. The system of claim 1, wherein the load element includes an antenna, and wherein the voltage pulse produces a high power microwave frequency pulse when coupled with the antenna.

16. A method of generating a high power pulse in a delivery device, comprising:
providing a capacitor electrode configuration coupled with a pulse forming line (PFL) in the munitions device, said capacitor configuration having an initial capacitance and a substantially constant charge; and
dynamically reducing the capacitance of the capacitor electrode configuration, while maintaining the substantially constant charge on the capacitor electrode configuration, wherein upon reduction of the capacitance, a voltage of the capacitor electrode configuration is increased and a voltage pulse is generated on the PFL.

17. The method of claim 16, further comprising coupling the PFL with a load element, wherein the voltage pulse propagates along the PFL to the load element.

18. The method of claim 17, wherein the load element includes an antenna, and wherein the voltage pulse produces a high power microwave frequency pulse when coupled with the antenna.

19. The method of claim 16, wherein the capacitor electrode configuration includes two conductive sheets wound up on two conducting rods in an interleaved cylindrical configuration, wherein reducing the capacitance includes winding the conductive sheets on said rods so as to reduce an area of overlap of said sheets, and wherein the PFL comprises a parallel wire transmission line.

20. The method of claim 16, wherein the capacitor electrode configuration includes planar or cylindrical interleaved conductive elements, wherein reducing the capacitance includes separating the conductive elements so as to reduce an area of overlap of said conductive elements.

21. The method of claim 16, wherein reducing the capacitance includes one or more of a) reducing an area of overlap of capacitor electrodes, b) increasing a distance between capacitor electrodes, and c) reducing a dielectric permittivity between capacitor electrodes.

22. The method of claim 16, wherein the delivery device comprises one of a UAV, a missile, a rocket, or a munitions device.
